(19) United States
(12) Patent Application Publication
(10) Pub. No.: US 2013/0026515 A1
(43) Pub. Date: Jan. 31, 2013

(54) LED PACKAGE WITH A FRESNEL LENS

(71) Applicant: Chao-Chuan CHEN, Taichung City (TW)

(72) Inventor: Chao-Chuan CHEN, Taichung City (TW)

(21) Appl. No.: 13/192,471

(22) Filed: Jul. 28, 2011

(51) Int. Cl. H01L 33/58

(52) U.S. Cl. 257/98; 257/E33.073

(57) ABSTRACT

A LED package with a Fresnel lens includes a base, a LED chip, a surrounding body and a lens. The lens is a Fresnel lens which refracts the beam of light from the LED chip to one definite direction for spotlighting the emitting light in a certain orientation.

### BACKGROUND OF THE INVENTION

1. Field of the Invention

The present invention relates to a LED package, and more particularly to a LED package with a Fresnel lens.

2. Description of Related Art

A LED (light-emitting diode) is a semiconductor light source. LEDs are not only used for indicating light in many devices, but also used for illumination. Introduced as a practical electronic component in 1962, early LEDs emitted low-intensity red light, but modern versions are available across the visible, ultraviolet and infrared wavelengths, with very high brightness. LEDs present many advantages over incandescent light sources including lower energy consumption, longer lifetime, improved robustness, smaller size, faster switching, and greater durability and reliability.

A conventional structure of a LED (as shown in FIG. 4) includes a base 61, a LED chip 62 and a surrounding body 63. The LED chip 62 is located on the surface of the base 61. The surrounding body 63 is located on the surface of the base 61. The LED chip 62 is surrounded by the surrounding body 63. A volume of encapsulating material 64 is injected into the region which is surrounded by the surrounding body 63. After the encapsulating material 64 solidify, the packaging of LED is done. However, the encapsulating material 64 is made of the limpid silicon. The limpid silicon can transmit the beam of light but cannot focus the beam of light. Thus, the conventional structure of a LED cannot be used for spotlighting.

The present invention has arisen to mitigate and/or obviate the disadvantages of the conventional. Further benefits and advantages of the present invention will become apparent after a careful reading of the detailed description with appropriate reference to the accompanying drawings.

### SUMMARY OF THE INVENTION

The main objective of the present invention is to provide an improved LED package.

To achieve the objective, a LED package with a Fresnel lens comprises a base, a LED chip, a surrounding body and a lens, wherein the LED chip is located on the surface of the base and is electrically connecting to the base; the surrounding body is located on the surface of the base; the LED chip is surrounded by the surrounding body; a volume of encapsulating material is injected into an inner region which is surrounded by the surrounding body and the LED chip is packaged with the encapsulating material; the lens is located above the surrounding body; a refractive surface is formed on the lens and refracts the beam of light from the LED chip to one definite direction, the lens is a Fresnel lens.

Further benefits and advantages of the present invention will become apparent after a careful reading of the detailed description with appropriate reference to the accompanying drawings.

### BRIEF DESCRIPTION OF THE DRAWINGS

FIG. 1 is a partial exploded view of a LED package with a Fresnel lens of the present invention;

FIG. 2 is an assembled view of the LED package with a Fresnel lens of the present invention;

FIG. 3 is a cross-sectional view of the LED package with a Fresnel lens along a line 33 shown in FIG. 2 for showing the refracted beams of light through the refractive surface of the Fresnel lens; and

FIG. 4 is a cross-sectional view of a prior art.

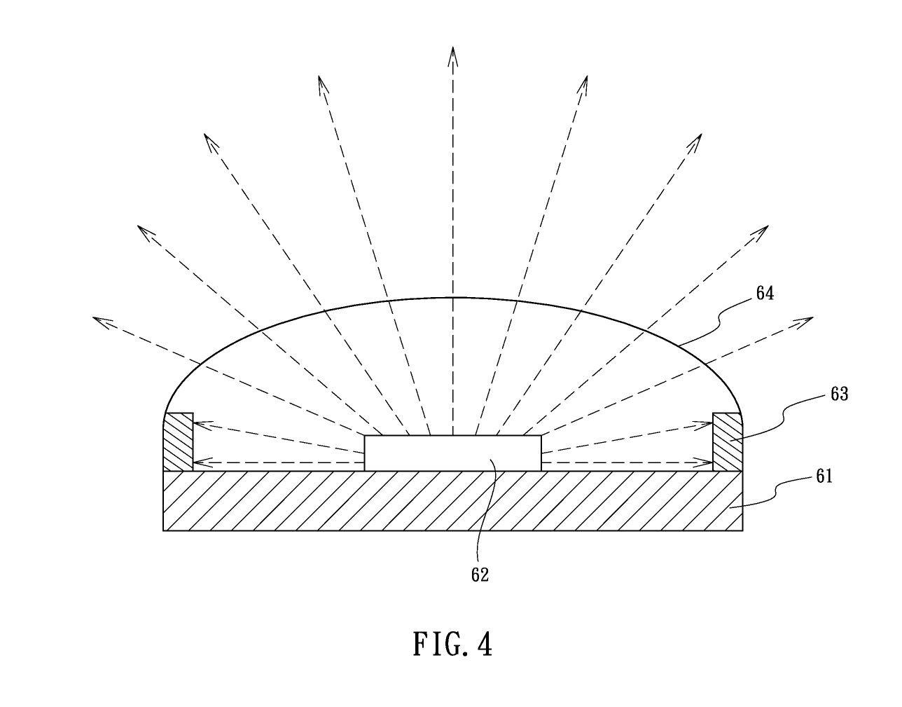

### DETAILED DESCRIPTION OF THE INVENTION

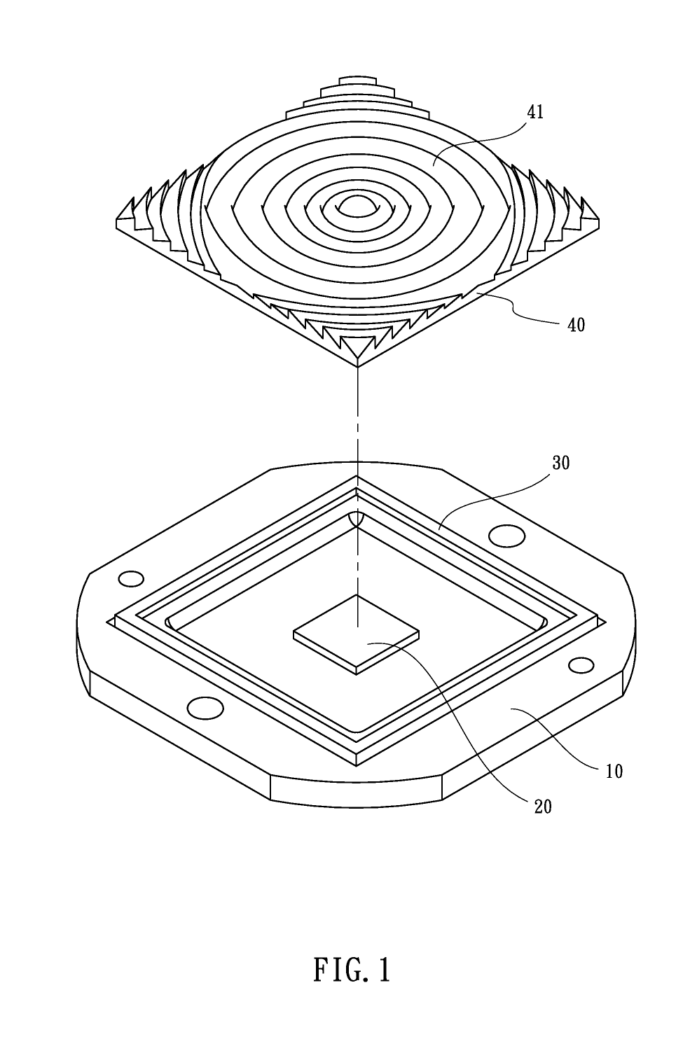

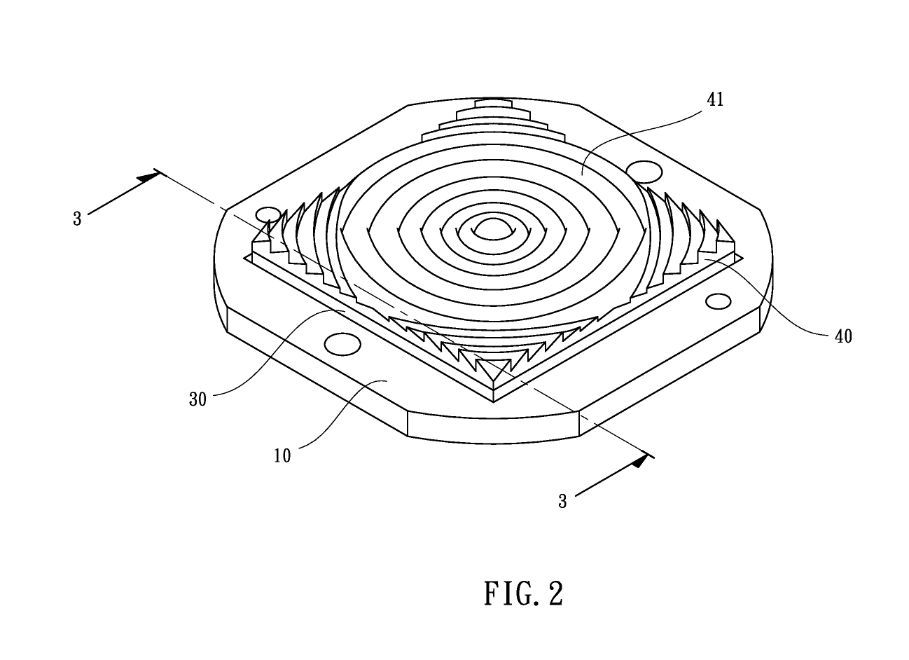

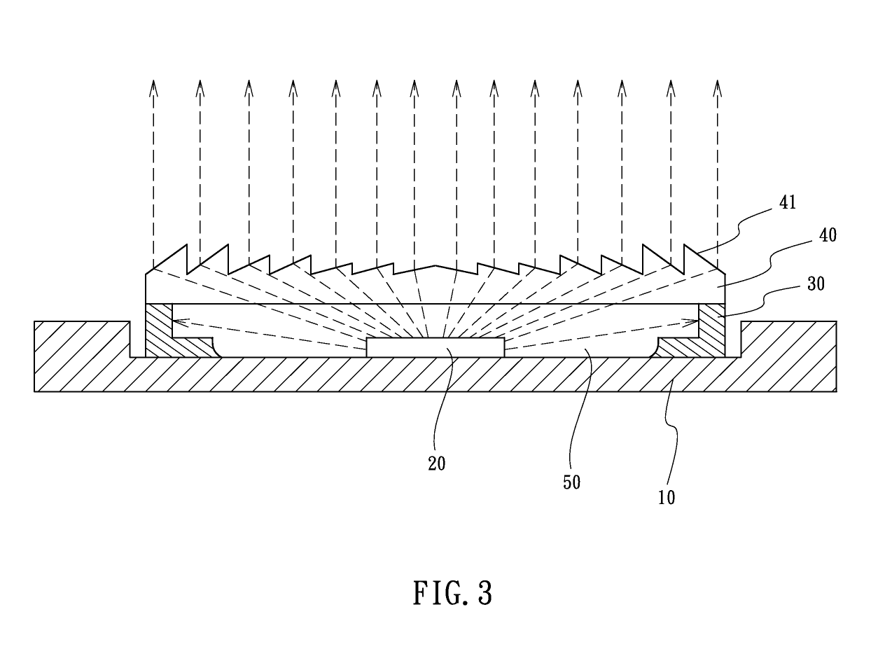

Referring to the drawings to FIGS. 1-3, a LED package with a Fresnel lens in accordance with the present invention comprises a base 10, a LED chip 20, a surrounding body 30 and a lens 40. The LED chip 20 is located on the surface of the base 10 and is electrically connecting to the base 10. The surrounding body 30 is located on the surface of the base 10. The LED chip 20 is surrounded by the surrounding body 30. A volume of encapsulating material 50 is injected into an inner region which is surrounded by the surrounding body 30. The LED chip 20 is packaged with the encapsulating material 50. The lens 40 is located above the surrounding body 30. A refractive surface 41 is formed on the lens 40. The refractive surface 41 refracts the beam of light from the LED chip 20 to one definite direction.

Furthermore, the lens 40 is a Fresnel lens. The lens 40 is usually made of glass or plastic. The lens 40 reduces the amount of required material compared to the conventional plano-convex lens by dividing the lens 40 into a set of concentric annular sections known as “Fresnel zones”. The “Fresnel zones” refracts the beam of light to a focal point so that the lens 40 has the same function with the conventional plano-convex lens. The encapsulating material 50 might be epoxy, spin-on glass, polyimide, B-staged bisbenzocyclobutene, ceramic material or glass.

Although the invention has been explained in relation to its preferred embodiment, it is to be understood that many other possible modifications and variations can be made without departing from the spirit and scope of the invention as hereinafter claimed.

What is claimed is:

1. A LED package with a Fresnel lens comprising:
a base, a LED chip, a surrounding body and a lens;
wherein the LED chip is located on the surface of the base and is electrically connecting to the base; the surrounding body is located on the surface of the base; the LED chip is surrounded by the surrounding body; a volume of encapsulating material is injected into an inner region which is surrounded by the surrounding body such that the LED chip is packaged with the encapsulating material; the lens is located above the surrounding body; a refractive surface is formed on the lens and refracts the beam of light from the LED chip to one definite direction.

2. The LED package having a Fresnel lens as claimed in claim 1, wherein the lens is a Fresnel lens.
